(19) United States
(12) Patent Application Publication
(10) Pub. No.: US 2026/0202765 A1
(43) Pub. Date: Jul. 16, 2026

(54) METHOD TO INFER AND ESTIMATE RETICLE TEMPERATURE BASED ON RETICLE SHAPE MEASUREMENTS

(71) Applicant: ASML Netherlands B.V., Veldhoven (NL)

(72) Inventor: Raaja Ganapathy SUBRAMANIAN, Maarheeze (NL)

(73) Assignee: ASML Netherlands B.V., Veldhoven (NL)

(21) Appl. No.: 19/135,168

(22) PCT Filed: Nov. 20, 2023
(86) PCT No.: PCT/EP2023/082417

§ 371 Date: Jun. 3, 2025

Related U.S. Application Data
(60) Provisional application No. 63/433,709, filed on Dec. 19, 2022.

(51) Int. Cl. G03F 7/00

(52) U.S. Cl. CPC G03F 7/70875; G03F 7/705; G03F 7/70725; G03F 7/7085

(57) ABSTRACT

Embodiments herein describe systems, methods, and devices for determining reticle temperature based on reticle shape measurements. System can comprises an illumination path configured to direct radiation onto a patterning device and a detection path configured to direct a portion of the radiation, after interaction with the patterning device, onto a detector configured to output a signal representative of the portion of the radiation beam. A controller can to receive the signal, determine information about a physical characteristic or alignment of the patterning device, and use the information to estimate a load temperature of the patterning device. The controller or another controller can estimated load temperature to compensate for temperature-induced magnification of the patterning device. The controller or the another controller compensates by adjusting a positioning of a stage or lens of the system.

### CROSS-REFERENCE TO RELATED APPLICATIONS

This application claims priority of U.S. application 63/433,709 which was filed on 19 Dec. 2022 and which is incorporated herein in its entirety by reference.

### FIELD

The present disclosure relates to systems, methods, and devices related to reticle temperature in lithographic apparatuses.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

To project a pattern on a substrate a lithographic apparatus may use electromagnetic radiation. The wavelength of this radiation determines the minimum size of features which can be formed on the substrate. A lithographic apparatus may use extreme ultraviolet (EUV) radiation, having a wavelength within the range 4-20 nm, for example 6.7 nm or 13.5 nm, or deep ultraviolet (DUV) radiation, having a wavelength in the range of about 120 to about 400 nm, for example 193 or 248 nm.

In DUV lithography, the radiation beam may cause thermal responses in the reticle. In particular, the reticle may absorb a large amount of thermal energy from the DUV radiation beam, which can cause the reticle to heat up and expand. Other sources, such as various mechatronic devices throughout the reticle handler and reticle stage modules, can contribute to reticle heating as well. Reticle heating, which results in a non-uniform thermal profile of the reticle, may serve as a major contribution to image distortion and overlay errors in the lithography system.

Currently reticle temperature is measured using a reticle temperature sensor (RTS). However, this suffers from drawbacks, such as deterioration of the sensor over time, which is referred to as sensor end-of-life (EOL). Another drawback is that the sensor itself possesses a temperature gradient that can result in a failure to capture fast exponential behavior of the reticle's temperature. Additionally, each measurement can take up to about 5 seconds per wafer, which causes additional overhead. What is needed is a better method of determining the temperature of the reticle.

### SUMMARY

The present disclosure provides systems and methods for determining reticle temperature based on reticle shape measurements.

In some embodiments, a system comprises an illumination path configured to direct radiation onto a patterning device and a detection path configured to direct a portion of the radiation, after interaction with the patterning device, onto a detector configured to output a signal representative of the portion of the radiation beam. A controller is configured to receive the signal, determine information about a physical characteristic or alignment of the patterning device, and use the information to estimate a load temperature of the patterning device.

In some embodiments, the controller or another controller uses the estimated load temperature to compensate for temperature-induced magnification of the patterning device.

In some embodiments the controller or the another controller compensates by adjusting a positioning of a stage or lens of the system.

In some embodiments, the controller or the another controller modifies the physical characteristic, another physical characteristic, or the alignment of the patterning device.

In some embodiments, the information comprises a magnification characteristic of the patterning device.

In some embodiments, the information comprises deformation of the patterning device.

In some embodiments, the controller is further configured to store a model of reticle shape measurements that correspond to deformation data.

In some embodiments, the controller is configured to use the information and output predicted deformation data using the model.

In some embodiments, the controller is further configured to use the predicted deformation data to predict an absolute rise or fall of the patterning device temperature.

In some embodiments, the patterning device is a reticle, and the controller uses the magnification characteristic to predict a reticle heating profile.

In some embodiments, a method for estimating a patterning device load temperature comprises receiving alignment data of the patterning device measured between the patterning device and a wafer, and determining a patterning device heating profile based on a previous location of the patterning device. A load temperature of the patterning device can be determined based on the alignment data, the heating profile, and a coefficient of thermal expansion of the patterning device. Future deformation of the patterning device can also be determined. An position adjustment a stage or a lens of a system that generated the alignment data can be made to compensate for the future deformation of the patterning device.

In some embodiments, the method can comprise directing radiation onto the patterning device and directing a portion of the radiation, after interaction with the patterning device, onto a detector configured to output a signal representative of the portion of the radiation beam. The method can determine information about a physical characteristic or alignment of the patterning device and use the information to estimate the load temperature of the patterning device.

In some embodiments, the method can use the information comprises using a magnification characteristic of the patterning device to estimate the load temperature.

In some embodiments, the method can use the information comprises using deformation information of the patterning device to estimate the load temperature.

In some embodiments, the method can store a model of the patterning device shape measurements that correspond to deformation data.

In some embodiments, the method can use the information to output a predicted deformation data using the model.

In some embodiments, the method can use the predicted deformation data to predict an absolute rise or fall of the patterning device temperature.

In some embodiments, the patterning device is a reticle, and the model is used to estimate reticle temperature based on reticle shape or reticle alignment data, a reticle heating profile based on a previous location of the reticle, and a coefficient of thermal expansion of the reticle's material.

Further features of the disclosure, as well as the structure and operation of various embodiments of the disclosure, are described in detail below with reference to the accompanying drawings. It is noted that the disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the disclosure and to enable a person skilled in the relevant art(s) to make and use the disclosure.

FIG. 1 is a schematic illustration of a lithographic apparatus, according to an exemplary aspect.

FIG. 2A is a schematic illustration of a lithographic cell, according to an exemplary aspect.

FIG. 2B is a schematic illustration of holistic lithography including a computer system to optimize a lithographic process, according to an exemplary aspect.

FIG. 3A is a schematic bottom perspective illustration of a reticle stage and a reticle, according to an exemplary aspect.

FIG. 3B is a schematic bottom plan illustration of the reticle stage shown in FIG. 3A.

FIG. 4A is a schematic top perspective illustration of a reticle exchange apparatus, according to an exemplary aspect.

FIG. 4B is a schematic partial cross-sectional illustration of the reticle exchange apparatus shown in FIG. 4A.

FIGS. 5A, 5B, and 5C illustrate experimental results of reticle thermo-mechanical key performance indicators over time, according to embodiments of the present disclosure.

FIGS. 6-8 illustrate various exemplary methods of predicting reticle temperature profiles, according to embodiments of the present disclosure.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more aspects that incorporate the features of this present invention. The disclosed aspect(s) merely exemplify the present invention. The scope of the invention is not limited to the disclosed aspect(s). The present invention is defined by the claims appended hereto.

The aspect(s) described, and references in the specification to “one aspect,” “an aspect,” “an example aspect,” “an exemplary aspect,” etc., indicate that the aspect(s) described may include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of one skilled in the art to effect such feature, structure, or characteristic in connection with other aspects whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” or “substantially” or “approximately” as used herein indicates the value of a given quantity that can vary based on a particular technology. Based on the particular technology, the term “about” or “substantially” or “approximately” can indicate a value of a given quantity that varies within, for example, 1-15% of the value (e.g., ±1%, ±2%, ±5%, ±10%, or ±15% of the value).

The term “parasitic thermal effects” as used herein indicates induced or internal stresses and/or deformations of a reticle, for example, due to heating and/or cooling the reticle (e.g., by resistive heating, gas flow cooling, exposing the reticle to a dose of radiation, etc.) or mechanical pressures and/or deformations from clamping and/or holding the reticle on the reticle stage.

The term “non-production substrate” as used herein indicates a substrate (e.g., a wafer) that is not part of a production lot and is not fabricated by a lithographic process into a device (e.g., an IC chip). For example, a non-production substrate can be a chuck temperature conditioning (CTC) wafer or calibration wafer for a reticle calibration method, for example, to calibrate a reticle heating model and to acclimate the reticle by exposing the reticle and the CTC wafer to a dose of radiation and measuring a reticle alignment and/or a reticle temperature.

The term “production substrate” as used herein indicates a substrate (e.g., a wafer) that is part of a production lot and is fabricated by a lithographic process into a device (e.g., an IC chip). For example, a production substrate can be a wafer (e.g., silicon) for fabrication and inline real-time calibration of a reticle heating model, for example, by exposing the reticle and the wafer to a dose of radiation and measuring a reticle alignment and/or a reticle temperature.

The term “reticle heating model” as used herein indicates a modal deformation approach (e.g., analysis of different reticle mode shapes) to determine reticle heating effects based on reticle alignment and/or reticle shape deformations and a finite element model (FEM) (e.g., COMSOL). For example, the reticle heating model can be deterministic (e.g., no random future states) or non-deterministic (e.g., including random future states) reticle heating effects. Further, the reticle heating model can be deemed a reticle heating execution algorithm (RHEA) that uses inline modal calibrations to determine the baseline reticle heating dynamics. The reticle heating model can be calibrated by exposing a reticle and a non-production substrate to a dose of radiation for inline real-time calibration of the reticle heating model. In some aspects, for example, the reticle heating model can be calibrated by exposing a reticle and a production substrate to a dose of radiation for inline real-time calibration of the reticle heating model. Other reticle heating models utilize a sensor-based approach (e.g., using RTS measurements) to calibrate the reticle heating model. This is described in further detail in U.S. Pat. Nos. 10,429,749, 10,281,825, and U.S. Publication No. 2020/0166854, which are incorporated by reference herein in their entireties.

Reticle heating causes changes in reticle properties that can affect the radiation path and cause fabrication errors (e.g., overlay). Reticle mechanical deformations (e.g., based on reticle temperature) can be calculated and decomposed into k-parameters. Each thermo-mechanical mode (e.g., eigenvector) can be modeled in time using modal participation factor u and time constant t. Measured overlay and/or alignment can be used to model the related k-parameter drifts, which can be used to calculate adjustments to the feed-forward parameters u and t. The reticle heating model can also include adjusting feed-forward parameters u and t. This is described in further detail in U.S. Pat. No. 10,429,749, U.S. Publication No. 2020/0166854, and WIPO Publication No. 2021/043519, which are incorporated by reference herein in their entireties.

The term “finite element model” or “FEM” as used herein indicates a method for numerically solving differential equations arising in the reticle heating model (e.g., heat transfer equations, structural analysis equations, fluid flow equations, etc.). For example, baseline reticle heating dynamics can be analyzed with the FEM through finite element analysis. This is described in further detail in U.S. Pat. Nos. 10,429,749, 10,281,825, and U.S. Publication No. 2020/0166854.

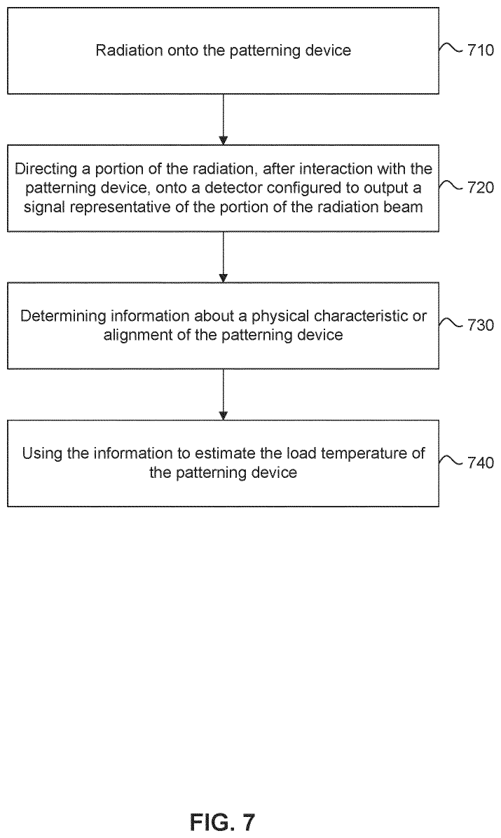

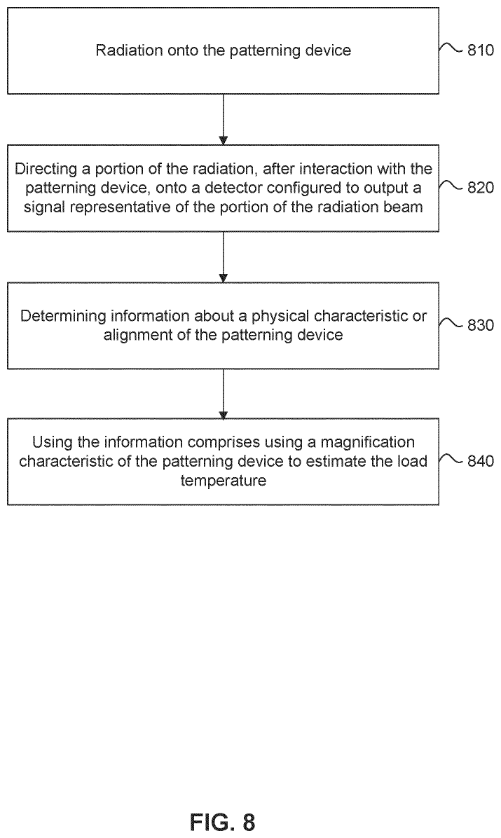

The term “key performance indicators” or “KPIs” or “k-parameters” as used herein indicates coefficients of polynomials that are fit to distortions of reticle alignment marks and/or edge alignment marks. The k-parameters parameterize the distortion of the imaging across the field of each substrate. For example, each k-parameter can describe a certain image distortion component (e.g., scaling error, barrel distortion, pincushion distortion, etc.). For example, two important k-parameters are k4 (e.g., k4/my shown in FIG. 7) that represents distortion in Y-axis magnification and k18 (e.g., k18/cshpy shown in FIG. 8) that represents distortion in Y-axis barrel shape. The k-parameters can be used as input to a lithographic process (e.g., lithographic apparatus LA, lithographic cell LC, control (controller) system CL) to correct the distortion. This is described in further detail in U.S. Pat. No. 10,429,749, U.S. Publication No. 2020/0166854, and WIPO Publication No. 2021/043519.

The term “inline real-time calibration” as used herein indicates calibration of the reticle heating model during actual fabrication of production substrates. For example, a calibration lot of production substrates can be avoided and rework of production substrates for calibration purposes can be reduced or avoided. The calibration can be done inline by exposing a reticle and a production substrate to a dose of radiation. Further, the calibration can be done in real-time (e.g., at a real-time frame rate or a computing rate of 2.56 seconds or less).

Aspects of the disclosure, such as the controller, may be implemented in hardware, firmware, software, or any combination thereof. Aspects of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions may be described herein as performing certain actions. However, it should be appreciated that such descriptions are merely for convenience and that such actions in fact result from computing devices, processors, controllers, or other devices executing the firmware, software, routines, instructions, etc., as would become apparent to persons skilled in the art.

Before describing such aspects in more detail, however, it is instructive to present example environments in which aspects of the present disclosure may be implemented.

### Exemplary Lithographic System

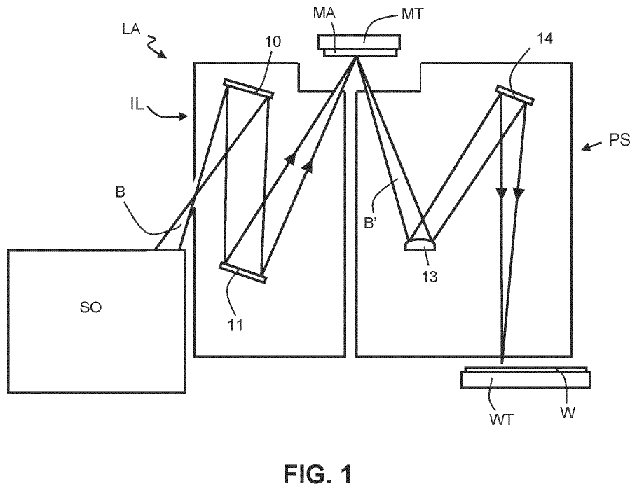

FIG. 1 shows a lithographic system comprising a radiation source SO and a lithographic apparatus LA. The radiation source SO is configured to generate an EUV and/or a DUV radiation beam B and to supply the EUV and/or DUV radiation beam B to the lithographic apparatus LA. The lithographic apparatus LA comprises an illumination system IL, a support structure MT (e.g., a mask table, a reticle table, a reticle stage) configured to support a patterning device MA (e.g., a mask, a reticle), a projection system PS, and a substrate table WT configured to support a substrate W.

The illumination system IL is configured to condition the EUV and/or DUV radiation beam B before the EUV and/or DUV radiation beam B is incident upon the patterning device MA. Thereto, the illumination system IL may include a faceted field mirror device 10 and a faceted pupil mirror device 11. The faceted field mirror device 10 and faceted pupil mirror device 11 together provide the EUV and/or DUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV and/or DUV radiation beam B interacts with the patterning device MA. This interaction may be reflective (as shown), which may be preferred for EUV radiation. This interaction may be transmissive, which may be preferred for DUV radiation. As a result of this interaction, a patterned EUV and/or DUV radiation beam B′ is generated. The projection system PS is configured to project the patterned EUV and/or DUV radiation beam B′ onto the substrate W. For that purpose, the projection system PS may comprise a plurality of mirrors 13, 14 which are configured to project the patterned EUV and/or DUV radiation beam B′ onto the substrate W held by the substrate table WT. The projection system PS may apply a reduction factor to the patterned EUV and/or DUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV and/or DUV radiation beam B′, with a pattern previously formed on the substrate W.

### Exemplary Lithographic Cell

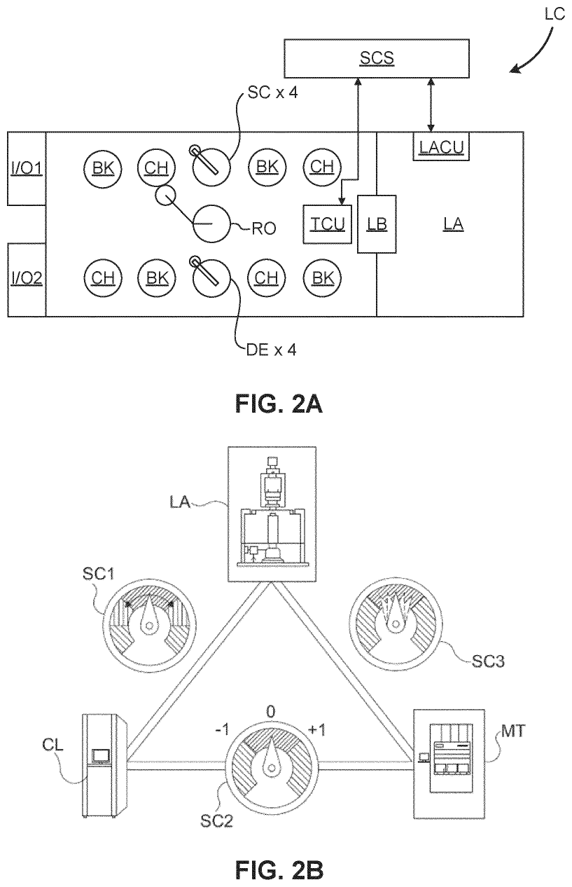

FIG. 2A shows a lithographic cell LC, also sometimes referred to as a lithocell or cluster. Lithographic apparatus LA may form part of lithographic cell LC. Lithographic cell LC may also include one or more apparatuses to perform pre-and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus LA. These devices, which are often collectively referred to as the track, are under the control of a track control unit TCU which is itself controlled by a supervisory control system SCS, which also controls the lithographic apparatus LA via lithography control unit LACU. Thus, the different apparatuses can be operated to maximize throughput and processing efficiency.

In order for the substrates W exposed by the lithographic apparatus LA to be exposed correctly and consistently, it is desirable to inspect substrates to measure properties of patterned substrates, for example, overlay errors between subsequent layers, line thicknesses, critical dimensions (CD), etc. For this purpose, inspection tools (e.g., metrology tool MT) may be included in lithographic cell LC and/or lithographic apparatus LA. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus or metrology tool MT, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of lithographic cell LC, integrated into lithographic apparatus LA, and/or be a stand-alone device. The inspection apparatus may measure the properties on a latent image (e.g., image in a resist layer after the exposure), on a semi-latent image (e.g., image in a resist layer after a post-exposure bake step), on a developed resist image (e.g., image in which the exposed or unexposed parts of the resist have been removed), or on an etched image (e.g., image after a pattern transfer step, such as etching).

### Exemplary Computer System

FIG. 2B shows a computer system CL, also referred to as a controller or processor. Computer system CL may be part of lithographic cell LC, integrated into lithographic apparatus LA, and/or be a stand-alone device. Computer system CL is configured to optimize a lithographic process, for example, calibrate a reticle heating model. Typically the patterning process in lithographic apparatus LA is an important step in the processing, which requires high accuracy of dimensioning and placement of structures on the substrate W. To ensure this high accuracy, three systems can be combined in a so-called “holistic” control environment as schematically depicted in FIG. 2B. As shown in FIG. 2B, the “holistic” environment can include lithographic apparatus LA, computer system CL, and metrology tool MT. For example, lithographic apparatus LA (a first system) can be connected to computer system CL (a second system) and metrology tool MT (a third system).

A key of such holistic lithography is to optimize the cooperation between these three systems to optimize a lithographic process, for example, to enhance the overall process window and provide tight controls loops to ensure that the patterning performed by lithographic apparatus LA stays within a process window. The process window defines a range of process parameters, for example, dose, focus, overlay, etc., within which a specific manufacturing process yields a defined result, for example, a functional semiconductor device—typically within which the process parameters in the lithographic process or patterning process are allowed to vary.

Computer system CL may, for example, use (e.g., part of) the design layout to be patterned to predict which resolution enhancement techniques to use and to perform computational lithography simulations and calculations, for example, to determine which mask layout and lithographic apparatus settings achieve the largest overall process window of the patterning process (shown in FIG. 2B by the double arrow in the first scale SC1). Typically, the resolution enhancement techniques are arranged to match the patterning possibilities of lithographic apparatus LA. Computer system CL may also be used to detect where within the process window lithographic apparatus LA is currently operating (e.g., using input from metrology tool MT) to predict whether defects may be present, for example, due to sub-optimal processing (shown in FIG. 2B by the arrow pointing “0” in the second scale SC2).

Metrology tool MT may provide input to computer system CL, for example, to enable accurate simulations and predictions. For example, metrology tool MT may provide alignment information. Metrology tool MT may provide feedback (e.g., via computer system CL) to lithographic apparatus LA to identify possible drifts, for example, in a calibration status of lithographic apparatus LA (shown in FIG. 2B by the multiple arrows in the third scale SC3). In lithographic processes, it is desirable to make frequent measurements of the structures created, for example, for process control and verification. Different types of metrology tools MT can be used, for example, to measure one or more properties relating to lithographic apparatus LA, a substrate W to be patterned, and/or reticle alignment. This is described in further details in U.S. Pat. No. 11,099,319 and WIPO Publication No. 2021/043519, which are incorporated by reference herein in their entireties.

### Exemplary Reticle Stage and Reticle

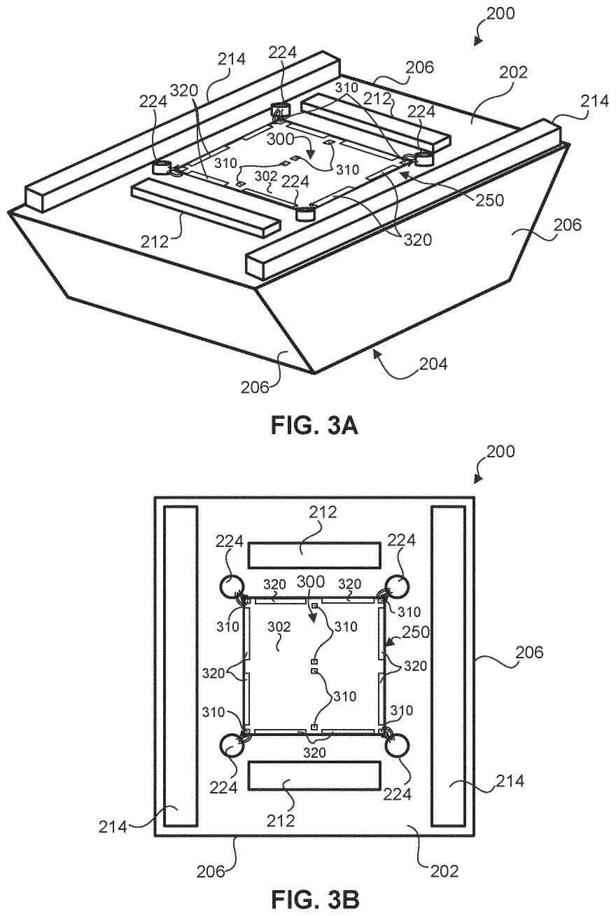

FIGS. 3A and 3B show schematic illustrations of reticle stage 200, according to exemplary aspects. FIG. 3A is a schematic bottom perspective illustration of reticle stage 200 and reticle 300, according to an example aspect. FIG. 3B is a schematic bottom plan illustration of reticle stage 200 and reticle 300 shown in FIG. 3A.

Reticle stage 200 (e.g., support structure MT) can be used in a lithographic apparatus (e.g., lithographic apparatus LA) to hold a patterning device (e.g., patterning device MA). Reticle stage 200 can include bottom stage surface 202, top stage surface 204, side stage surfaces 206, clamp 250, reticle cage 224, and/or reticle 300. In some aspects, reticle stage 200 with reticle 300 can be implemented in lithographic apparatus LA. For example, reticle stage 200 can be support structure MT in lithographic apparatus LA. In some aspects, reticle 300 can be disposed on bottom stage surface 202 and held by clamp 250. For example, as shown in FIGS. 3A and 3B, reticle 300 can be disposed on clamp 250 (e.g., an electrostatic clamp) at a center of bottom stage surface 202 with reticle frontside 302 facing perpendicularly away from bottom stage surface 202. In some aspects, reticle cage 224 can be disposed on bottom stage surface 202. For example, as shown in FIGS. 3A and 3B, reticle 300 can be disposed at a center of bottom stage surface 202 and secured by reticle cages 224 adjacent to each corner of reticle 300.

In some lithographic apparatuses, for example, lithographic apparatus LA, reticle stage 200 with clamp 250 can be used to hold and position reticle 300 for scanning or patterning operations. In some aspects, as shown in FIGS. 3A and 3B, reticle stage 200 can include first encoder 212 and second encoder 214 for positioning operations. For example, first and second encoders 212, 214 can be interferometers. First encoder 212 can be attached along a first direction, for example, a transverse direction (i.e., X-direction) of reticle stage 200. And second encoder 214 can be attached along a second direction, for example, a longitudinal direction (i.e., Y-direction) of reticle stage 200.

As shown in FIGS. 3A and 3B, reticle 300 can include reticle frontside 302, alignment mark 310, and/or edge alignment mark 320. Alignment mark 310 is configured to measure a reticle alignment between reticle 300 and a substrate (e.g., substrate W, non-production substrate, production substrate). In some aspects, as shown in FIGS. 3A and 3B, one or more alignment marks 310 can be disposed in the corners and/or the center of reticle 300 for an RA measurement. Edge alignment mark 320 is configured to measure a reticle shape deformation of reticle 300 due to thermal expansion when reticle 300 is not within a predetermined temperature (e.g., at 22° C.±0.2° C.). In some aspects, as shown in FIGS. 3A and 3B, one or more edge alignment marks 320 can be disposed along the perimeter edges (e.g., horizontal and vertical edges) of reticle 300 for a reticle shape deformation (RSD) measurement. In some aspects, the results of the RA measurement and/or the RSD measurement can be converted to a reticle temperature, for example, by a FEM that solves for temperature based on reticle alignment and/or reticle deformation.

### Exemplary Reticle Exchange Apparatus

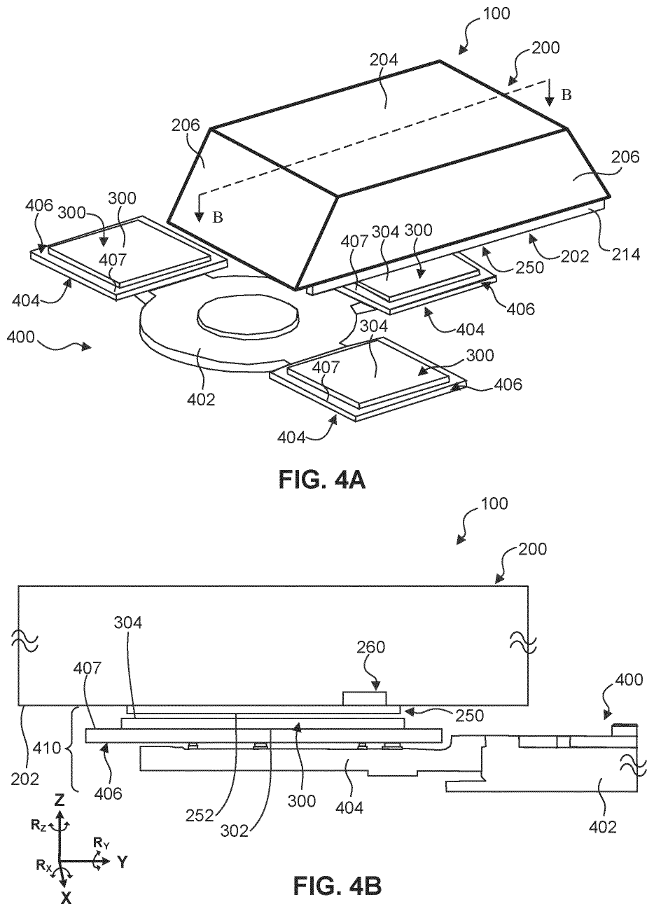

FIGS. 4A and 4B show schematic illustrations of reticle exchange apparatus 100, according to exemplary aspects. FIG. 4A is a schematic top perspective illustration of reticle exchange apparatus 100, according to an exemplary aspect. FIG. 4B is a schematic partial cross-sectional illustration of reticle exchange apparatus 100 shown in FIG. 4A.

Reticle exchange apparatus 100 can be configured to reduce reticle exchange time and thermal stresses in reticle 300 to increase overall throughput, for example, in lithographic apparatus LA. In some aspects, reticle exchange apparatus 100 can reduce stress in reticle 300 by removing reticle 300 from reticle stage 200 to in-vacuum robot (IVR) 400. For example, reticle exchange apparatus 100 can quickly unclamp reticle 300 from reticle cages 224 and clamp 250 and transfer reticle 300 to IVR 400 to release thermal stress in reticle 300. In some aspects, reticle exchange apparatus 100 can reduce stress in reticle 300 and increase throughput by unclamping and transferring reticle 300 from reticle stage 200 to IVR 400 and quickly returning and clamping reticle 300 back to reticle stage 200. As shown in FIGS. 4A and 4B, reticle exchange apparatus 100 can include reticle stage 200, clamp 250, and IVR 400.

IVR 400 can include reticle handler 402 with one or more reticle handler arms 404. In some aspects, reticle handler 402 can be a rapid exchange device (RED), which is configured to efficiently rotate and minimize reticle exchange time. Reticle handler arm 404 can include reticle baseplate 406 configured to hold an object, for example, reticle 300. In some aspects, reticle baseplate 406 can be an extreme ultraviolet inner pod (EIP) for reticle 300. Reticle baseplate 406 includes reticle baseplate frontside 407, and reticle 300 includes reticle backside 304.

As shown in FIGS. 4A and 4B, reticle baseplate 406 can hold reticle 300 such that reticle baseplate frontside 407 and reticle backside 304 each face bottom stage surface 202 and clamp frontside 252. For example, reticle baseplate frontside 407 and reticle backside 304 can be facing perpendicularly away from bottom stage surface 202 and clamp frontside 252. As shown in FIG. 4B, reticle exchange apparatus 100 can include reticle exchange area 410, which is the cross-sectional area between clamp 250, reticle 300, reticle baseplate 406, and reticle handler arm 404 during a reticle exchange process.

In one example, during a reticle exchange process, reticle handler arm 404 of reticle handler 402 positions reticle 300 on reticle baseplate 406 towards clamp 250 in reticle exchange area 410. As described above, a reticle handoff from reticle handler 402 to clamp 250 and vice-versa can release thermal stress in reticle 300 and reduce parasitic thermal effects in reticle 300.

### Exemplary Reticle Calibration Methods

As discussed above, a lithographic apparatus (e.g., lithographic apparatus LA) can include a reticle stage (e.g., support structure MT, reticle stage 200) to hold a patterning device (e.g., patterning device MA, reticle 300) to transfer a pattern to a substrate (e.g., substrate W). Reticle heating and/or cooling can cause changes in reticle properties that can affect the radiation beam path (e.g., focus) and cause distortions in the patterned substrate (e.g., overlay errors). Changes in reticle properties can be modeled and corrected with a reticle heating model. Current reticle heating models rely on a sensor-based application specific approach to calibrate the reticle heating model with an RTS and require a calibration lot of production wafers.

In some examples, this approach can be inaccurate and inefficient since the RTS can exhibit errors, can introduce unnecessary delays, and can require rework of production wafers. In some aspects, the RTS has a temperature gradient variation of about ±0.6° C., which can cause an overlay mismatch of about 1 nm/° C. Also, in some aspects each reticle temperature measurement with the RTS takes about five seconds per wafer, which can introduce additional delays. Current reticle pre-conditioning techniques can slow down wafer processing. Further, variations in a reticle's thermo-mechanical properties prior to calibration can amplify and exacerbate an overlay mismatch (e.g., increase from 1 nm/° C. to over 2.1 nm/° C.). In addition, production wafers used for calibration may be reworked over time, which can introduce additional delays and reduce overall throughput.

Aspects of reticle calibration apparatuses, systems, and methods as discussed in PCT/EP2022/078447, which is incorporated herein by reference in its entirety, can increase calibration accuracy and speed of a reticle heating model, reduce conditioning times of a reticle, reduce stress in the reticle, avoid rework of production substrates, and/or increase fabrication throughput and yield of a lithographic process.

### Exemplary Methods of Improving Reticle Calibration Methods by Deriving Reticle Temperature Information

As noted above, current reticle calibration and/or measurement systems and methods can employ sensor-based direct measurement approaches. In some aspects, the current disclosure increases performance of such current temperature sensors.

In some embodiments, systems and methods are disclosed for determining reticle temperature by inferring reticle temperature based on reticle shape measurements. For example, systems and methods can determine a load temperature of the patterning device based on alignment data, a heating profile of the reticle, and a coefficient of thermal expansion of the reticle.

Reticles are positioned onto and off of the reticle station usinga reticle handler. Such systems are described, for example in U.S. Pat. No. 10,284,830, which is incorporated herein by reference in its entirety. Such systems can employ reticle heating correction (RHC). In some examples, it may not be uncommon for high temperature reticles to arrive even with temperature preconditioning. In some aspects, reticles are conditioned thermally before exposure in the scanner to achieve a well-defined reticle temperature, which is desired for the optimal performance of the RHC, especially on systems that do not rely on reticle temperature sensor (RTS) measurements to measure the initial reticle temperature. In some aspects, reticles can be quickly conditioned to a desired temperature (e.g., a 22+/−2 degree C reticle can be conditioned within 5 minutes towards 22.18° C.), while in a normal slot a reticle may be conditioned slowly (within 45 minutes to 22.3-22.8° C.).

In embodiments where reticles need to be conditioned they can be delivered from outside the system by a user's reticle delivery system or from different locations in the lithography system (scanner). The actual arrival temperature of the reticle depends on its history, such as arriving from: outside the scanner, in which case the reticle temperature may range between about 20-24° C.; the reticle station, in which case the reticle temperature may range between about 22-24° C., depending on the exposure dose and throughput of the lot where the reticle was exposed; an integrated reticle inspection system (IRIS), in which case the reticle temperature may range between about 22.2-22.5° C., depending on the residence time in the IRIS; or from an internal reticle library (IRL) slot, in which case the reticle temperature may range between about 22-24° C., depending its previous history and residence time in the normal slot. In some aspects, measuring such fine temperature difference can utilize sophisticated sensors that may suffer the above shortcomings.

Embodiments of the present disclosure determine reticle temperature using reticle shape/align (RA) measurements. In some aspects, the RA measurements can have a much smaller reproducibility (K) than that of the RTS. Current RTS reproducibility is about 0.6K, compared to 0.05K achieved by the presently disclosed systems and methods. In some aspects, RA measurement in connection with the presently disclosed systems and methods take about 1 second, thus having a lower throughput impact than using current RTS that take more than about 5 seconds per measurement, which improves the throughput impact by a factor of five. And the presently disclosed systems and methods may not require modifying or adding new hardware to the reticle system.

In some embodiments, reticle magnification data is used together with data about the physics and the mechanical properties of the reticle, so as to determine how much the reticle is going to change in temperature. For example, if the system is typically at 22° C. and the deformation data is two nanometers per centimeter in magnification, thermal expansion coefficients of the reticle can be used to calculate that the reticle is heating up by 0.4° C. Such temperature information can be fed back to the controller better predict a reticle heating profile.

As noted above, methods of reducing effects of reticle heating and/or cooling in a lithographic process can include calibrating a linear time invariant reticle heating model, or a reticle heating execution algorithm (RHEA). In some aspects, the method can predict distortions of the reticle using the reticle heating model and inputs in the lithographic process followed by calculating and applying a correction in the lithographic process on the basis of the predicted distortions of the reticle. In some aspects, reticle heating mode shapes can be obtained on the basis of sensor data and/or simulation data. The simulation data may for instance can be generated by a finite element model describing a relationship between reticle heating input parameters and distortions of reticle caused by the reticle heating caused by these input parameters.

In some embodiments, a physical characteristic of the reticle can be used, such as a dimension of known shapes on the reticle or a deformation of the reticle based on a magnification measurement. In some embodiments, a magnification measurement is taken of the reticle, which is a property of length, can be used to infer or otherwise estimate the temperature of the reticle. For example, reticles comprising quartz have a fixed temperature coefficient of thermal expansion (CTE) (about 5.5×10−7 cm/cm° C.). Reticles may comprise other materials with known CTE. Accordingly, a temperature profile of the reticle can be calculated using the CTE of the reticle and the magnification measurement.

In some embodiments, measurements using a PARIS (Parallel Integrated Lens Interferometry At Scanner sensor) can be used. Such sensor are known to persons skilled in the art. But other known measurement techniques can be used.

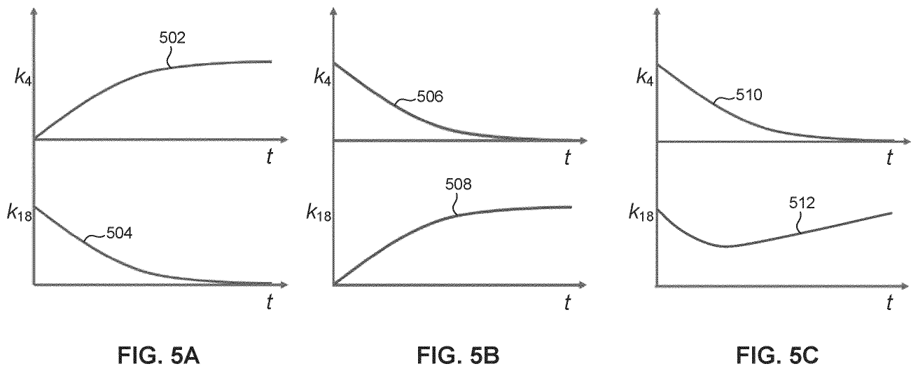

FIGS. 5A, 5B, and 5C illustrate experimental results of reticle thermo-mechanical key performance indicators (KPI) over time, according to some embodiments. FIG. 5A shows an example reticle heating curve. In one aspect, as the reticle warms up, the relative peak power change (K4) 502 increases, and the (in)voluntary imbalance (K18) 504 decreases. Conversely, FIG. 5B shows an example reticle cooling curve. In one aspect, as the reticle cools down, the relative peak power change (K4) 506 decreases, and the (in)voluntary imbalance (K18) 508 increases. FIG. 5C shows an example reticle hot-reticle curve. In one aspect, as the reticle hot reticle cools down, the relative peak power change (K4) 510 decreases, similar to 506, and the (in)voluntary imbalance (K18) 512 indicates heating followed by cooling.

In some aspects, with thermo-mechanical key performance indicators (KPI), measurements of the reticle characteristic in combination with the reticle physical properties can be used to determine a reticle load temperature. That is, reticle load temperature can be calculated using a physical property, such as the coefficient of thermal expansion of quartz, the combination of k4 and k18 as measured via reticle alignment sensors in the lithography tool, and then scale with a ratio of 1 nm/cm in k 4 to 0.2° C., to infer the reticle temperature.

In some aspects, the reticle load temperature data can then be used by the reticle heating controller to bring the reticle heating profile to zero. In other words, the reticle heating controller can predict the heating or cooling (e.g., caused by EUV imaging) and then compensate by either further heating or cooling by the system to maintain a desired target temperature of the reticle. Thus, any user desired reticle thermal state (e.g., the temperature when the reticle is loaded into the system or some other target temperature state) can be more readily maintained.

In some aspects, reticle testing time/throughput is increased without the need for additional hardware. In some aspect, existing information about the reticle is used by the controller to generate the reticle load temperature data.

Accordingly, not only can the reticle temperature be estimated, but the absolute reticle temperature rise based on the reticle shape measurements can be predicted (e.g., using k4 and k18).

In some embodiments, if the a reticle heating is an exponential curve, the controller is configured to heat or cool the reticle in an opposite manner to attenuate that specific the reticle heating behavior.

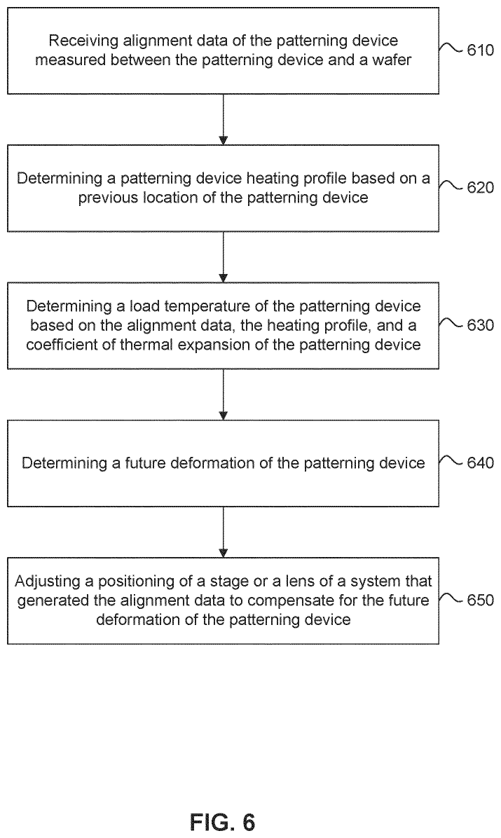

FIGS. 6-8 illustrate various exemplary methods of predicting reticle temperature profiles, according to the present disclosure. It is to be appreciated that the operations may be performed in a different order, or may not require all steps shown.

In some embodiments, such as illustrated in FIG. 6, the system controller receives alignment data of the patterning device measured between the patterning device and a wafer at a step 610. The controller can determine a patterning device heating profile, for example, based on a previous location of the patterning device, at a step 620. The controller can determine a load temperature of the patterning device based on the alignment data, the heating profile, and a coefficient of thermal expansion of the patterning device, at a step 630. The controller can determine future deformation of the patterning device at a step 640. In some embodiments, the controller can adjust a positioning of a stage or a lens of the system that generated the alignment data to compensate for the future deformation of the patterning device at a step 650.

In some embodiments, such as illustrated in FIG. 7, the projection system directs radiation onto the patterning device at a step 710. Then a portion of the radiation, after interaction with the patterning device, is directed onto a detector configured to output a signal representative of the portion of the radiation beam at a step 720. The controller can determine information about a physical characteristic or alignment of the patterning device based on the signal at a step 730. Using than information, the controller can estimate the load temperature of the patterning device at a step 740.

In other embodiments, such as illustrated in FIG. 8, the projection system directs radiation onto the patterning device at a step 810. Then a portion of the radiation, after interaction with the patterning device, is directed onto a detector configured to output a signal representative of the portion of the radiation beam at a step 820. The controller can determine information about a physical characteristic or alignment of the patterning device based on the signal at a step 830. The information can be a magnification characteristic of the patterning device that is used by the controller to estimate the load temperature at a step 840. Alternatively, deformation information of the patterning device can be used to estimate the load temperature.

Various embodiments of the present systems and methods are disclosed in the subsequent list of numbered clauses:
1. A system comprising:
   an illumination path configured to direct radiation onto a patterning device;
   a detection path configured to direct a portion of the radiation, after interaction with the patterning device, onto a detector configured to output a signal representative of the portion of the radiation beam; and
   a controller configured to receive the signal, determine information about a physical characteristic or alignment data corresponding to the patterning device, and use the information to estimate a load temperature of the patterning device.
2. The system of clause 1, wherein the controller or another controller uses the estimated load temperature and/or relative temperature variation to compensate for temperature-induced deformation of the patterning device.
3. The system of clause 2, wherein the controller or the another controller compensates by adjusting a positioning of a stages or lens of the system.
4. The system of clause 2, wherein the controller or the another controller modifies the physical characteristic, another physical characteristic, or alignment of the patterning device.
5. The system of clause 1, wherein the information comprises a magnification characteristic of the patterning device.
6. The system of clause 1, wherein the information comprises deformation of the patterning device.
7. The system of clause 1, wherein the controller is further configured to store a model of reticle shape measurements that correspond to deformation data.
8. The system of clause 7, wherein the controller is configured to use the information and output predicted deformation data using the model.
9. The system of clause 8, wherein the controller is further configured to use the predicted deformation data to predict an absolute rise or fall of the patterning device temperature.
10. The system of clause 1, wherein the patterning device is a reticle, and the controller uses the magnification characteristic to predict a reticle heating profile.
11. A method for estimating a patterning device load temperature, comprising:
   receiving alignment data of the patterning device measured between the patterning device and a wafer;
   determining a patterning device heating profile based on a previous location of the patterning device;
   determining a load temperature of the patterning device based on the alignment data, the heating profile, and a coefficient of thermal expansion of the patterning device;
   determining a future deformation of the patterning device; and
   adjusting a positioning of a stage or a lens of a system that generated the alignment data to compensate for the future deformation of the patterning device.
12. The method of clause 11, further comprising:
   directing radiation onto the patterning device;
   directing a portion of the radiation, after interaction with the patterning device, onto a detector configured to output a signal representative of the portion of the radiation beam;
   determining information about a physical characteristic or alignment of the patterning device; and
   using the information to estimate the load temperature of the patterning device.
13. The method of clause 12, wherein using the information comprises using a magnification characteristic of the patterning device to estimate the load temperature.
14. The method of clause 12, wherein using the information comprises using deformation information of the patterning device to estimate the load temperature.
15. The method of clause 11, further comprising storing a model of the patterning device shape measurements that correspond to deformation data.
16. The method of clause 15, further comprising using the information to output a predicted deformation data using the model.
17. The method of clause 16, further comprising using the predicted deformation data to predict an absolute rise or fall of the patterning device temperature.
18. The method of clause 15, wherein the patterning device is a reticle, and the model is used to estimate reticle temperature based on reticle shape or reticle alignment data, a reticle heating profile based on a previous location of the reticle, and a coefficient of thermal expansion of the reticle's material.
19. A lithography tool comprising the system of clause 1.
20. The lithography tool of clause 19, wherein the controller or another controller uses the estimated load temperature and/or relative temperature variation to compensate for temperature-induced deformation of the patterning device.

Although specific reference may be made in this text to a “reticle,” it should be understood that this is just one example of a patterning device and that the embodiments described herein may be applicable to any type of patterning device. Additionally, the embodiments described herein may be used to provide safety support for any object to ensure a clamping failure does not cause the object to fall and damage either itself or other equipment.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track unit (a tool that typically applies a layer of resist to a substrate and develops the exposed resist), a metrology unit and/or an inspection unit. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the disclosure in the context of optical lithography, it will be appreciated that the disclosure can be used in other applications, for example imprint lithography, and where the context allows, is not limited to optical lithography. In imprint lithography a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present disclosure is to be interpreted by those skilled in relevant art(s) in light of the teachings herein.

The term “substrate” as used herein describes a material onto which material layers are added. In some embodiments, the substrate itself can be patterned and materials added on top of it may also be patterned, or may remain without patterning.

Although specific reference can be made in this text to the use of the apparatus and/or system according to the disclosure in the manufacture of ICs, it should be explicitly understood that such an apparatus and/or system has many other possible applications. For example, it can be employed in the manufacture of integrated optical systems, guidance and detection patterns for magnetic domain memories, LCD panels, thin-film magnetic heads, etc. The skilled artisan will appreciate that, in the context of such alternative applications, any use of the terms “reticle,” “wafer,” or “die” in this text should be considered as being replaced by the more general terms “mask,” “substrate,” and “target portion,” respectively.

While specific embodiments of the disclosure have been described above, it will be appreciated that the disclosure can be practiced otherwise than as described. The description is not intended to limit the disclosure.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of the present disclosure should not be limited by any of the above-described exemplary embodiments, but should be defined only in accordance with the following claims and their equivalents.

1. A system comprising:
an illumination path configured to direct radiation onto a patterning device;
a detection path configured to direct a portion of the radiation, after interaction with the patterning device, onto a detector configured to output a signal representative of the portion of the radiation beam; and
a controller configured to receive the signal, determine information about a physical characteristic or alignment data corresponding to the patterning device, and use the information to estimate a load temperature of the patterning device.

2. The system of claim 1, wherein:
the controller or another controller uses the estimated load temperature and/or relative temperature variation to compensate for temperature-induced deformation of the patterning device;
the controller or the another controller compensates by adjusting a positioning of a stages or lens of the system; and
the controller or the another controller modifies the physical characteristic, another physical characteristic, or alignment of the patterning device.

3. The system of claim 1, wherein the information comprises a magnification characteristic of the patterning device.

4. The system of claim 1, wherein the information comprises deformation of the patterning device.

5. The system of claim 1, wherein:
the controller is further configured to store a model of reticle shape measurements that correspond to deformation data;
the controller is configured to use the information and output predicted deformation data using the model; and
the controller is further configured to use the predicted deformation data to predict an absolute rise or fall of the patterning device temperature.

6. The system of claim 1, wherein the patterning device is a reticle, and the controller uses the magnification characteristic to predict a reticle heating profile.

7. A method for estimating a patterning device load temperature, comprising:
receiving alignment data of the patterning device measured between the patterning device and a wafer;
determining a patterning device heating profile based on a previous location of the patterning device;
determining a load temperature of the patterning device based on the alignment data, the heating profile, and a coefficient of thermal expansion of the patterning device;
determining a future deformation of the patterning device; and
adjusting a positioning of a stage or a lens of a system that generated the alignment data to compensate for the future deformation of the patterning device.

8. The method of claim 7, further comprising:
directing radiation onto the patterning device;
directing a portion of the radiation, after interaction with the patterning device, onto a detector configured to output a signal representative of the portion of the radiation beam;
determining information about a physical characteristic or alignment of the patterning device; and
using the information to estimate the load temperature of the patterning device.

9. The method of claim 8, wherein using the information comprises using a magnification characteristic of the patterning device to estimate the load temperature.

10. The method of claim 8, wherein using the information comprises using deformation information of the patterning device to estimate the load temperature.

11. The method of claim 7, further comprising:
storing a model of the patterning device shape measurements that correspond to deformation data; and
using the information to output a predicted deformation data using the model.

12. The method of claim 11, further comprising using the predicted deformation data to predict an absolute rise or fall of the patterning device temperature.

13. The method of claim 11, wherein the patterning device is a reticle, and the model is used to estimate reticle temperature based on reticle shape or reticle alignment data, a reticle heating profile based on a previous location of the reticle, and a coefficient of thermal expansion of the reticle's material.

14. A lithography tool comprising the system of claim 1.

15. The lithography tool of claim 14, wherein the controller or another controller uses the estimated load temperature and/or relative temperature variation to compensate for temperature-induced deformation of the patterning device.
